(19) United States
(12) Patent Application Publication
(10) Pub. No.: US 2023/0137460 A1
(43) Pub. Date: May 4, 2023

(54) METHOD FOR PRODUCING A VIA IN A CARRIER LAYER PRODUCED FROM A CERAMIC AND CARRIER LAYER HAVING A VIA

(71) Applicant: Rogers Germany GmbH, Eschenbach (DE)

(72) Inventors: Karsten Schmidt, Eschenbach (DE); Stefan Britting, Schnaittach (DE); Andreas Meyer, Wenzbach (DE); Rainer Herrmann, Warmensteinach (DE); Martin Reger, Immenreuth (DE)

(21) Appl. No.: 16/628,579

(22) PCT Filed: Jul. 4, 2018
(86) PCT No.: PCT/EP2018/068022

§ 371 Date: Apr. 8, 2020

(30) Foreign Application Priority Data
Jul. 4, 2017 (DE) 10 2017 114 891.4

(51) Int. Cl. H01L 23/15; H01L 23/498; H05K 1/03; H05K 1/09; H05K 3/40

(52) U.S. Cl. CPC H01L 23/15; H01L 23/49838; H01L 23/49827; H05K 1/0306; H05K 1/092; H05K 3/4061

(57) ABSTRACT

A method for making a via (3) in a carrier layer (1) made of a ceramic comprising:

providing the carrier layer (1),

realizing a passage recess (2) in the carrier layer (1),

at least partially filling the passage recess (2) with a paste (3), and

performing a bonding process, in particular an active soldering process or a DCB process, for bonding a metallization (5) to the carrier layer (1), the via (3′) being realized from the paste (3) in the passage recess (2) when the bonding process is performed.

### CROSS-REFERENCE TO RELATED APPLICATIONS

This application is a National Stage filing of PCT/EP2018/068022, filed Jul. 4, 2018, which claims priority to DE 10 2017 114 891.4, filed Jul. 4, 2017, both of which are incorporated by reference in their entirety herein.

### BACKGROUND

The present invention concerns a method for producing a via in a carrier layer made of a ceramic and a carrier layer having a via.

Such carrier substrates are known, for example, as printed circuit boards or circuit boards. Typically, metallizations are arranged on the top side of the carrier substrate, which can later be used to form conductor paths. For special applications, such carrier layers have proven to be particularly advantageous, which have an insulation layer with high electrical insulation strength for the electrical insulation of the individual electrical components and conductor tracks, e.g. a carrier layer made of ceramic.

In order to enable the most compact possible arrangement of electrical or electronic components and to reduce or suppress parasitic induction effects, it makes sense to connect an additional metallization not only to the top side of the carrier but also to the underside of the carrier opposite to the top side of the carrier and to connect the metallizations opposite to each other, e.g. by a via through the carrier layer, in an electrically conductive manner. Examples are known from DE 197 53 149 A1 or DE 19 945 794 C2.

From JP H06-13 726 A a ceramic substrate having a via is known. The via is realized when the metallization is connected to the upper side. For this purpose, a paste containing silver and copper is inserted into a corresponding hole.

EP 1 478 216 A1 describes a method a paste being introduced into a passage hole and is cured before the copper foil is applied.

### SUMMARY

It is an object of this invention to provide an improved method compared to the methods known from the state of the art, with which these vias can be produced simply and controlled.

This object is solved by a method for producing a via in a ceramic carrier layer, the method including providing the carrier layer; realizing a passage recess in the carrier layer; at least partially filling the passage recess with a paste; and performing a bonding process for bonding a metallization to the carrier layer, in particular an active soldering process or a DCB process, the via being realized from the paste in the via. A carrier layer is also described.

Further advantages and features of the invention result from the dependent claims as well as from the description and attached figures.

### BRIEF DESCRIPTION OF THE FIGURES

FIG. 1a to 1d: show a method for producing a via in a carrier layer made of a ceramic material according to an exemplary embodiment of the present invention

FIG. 2: shows a top view of a carrier layer having a via according to an exemplary embodiment of the present invention.

### DETAILED DESCRIPTION

According to the invention, a method is provided for forming a via in a carrier layer made of a ceramic comprising:

providing the carrier layer,

realizing a passage recess in the carrier layer,

at least partially filling the passage recess with a paste, and

performing a bonding process for bonding a metallization to the carrier layer, in particular an active soldering process or a DCB process, the via being realized from the paste in the via, when the bonding process is performed.

In contrast to state of the art methods, the via is advantageously produced during the active soldering process for bonding the metallization to the carrier layer. The simultaneous formation of the via saves the additional work step of forming the via, being otherwise necessary. In particular, in the active soldering process it is utilized that the temperatures used in the active soldering process can also be used to form the via. Particularly, it is intended that the paste comprises an active soldering material. This may be the same active solder material used to form the bond between the carrier layer and the metallization, or another solder material such as a glass-filled brazing alloy, in particular based on AgCu. If the metallization is connected by means of a DCB process, a paste is preferably used whose melting range is below the temperature provided for in the DCB process.

In particular, it is provided that the carrier layer has Al₂O₃, Si₃N₄, AlN or an HPSX ceramic (i.e. a ceramic with an Al₂O₃ matrix comprising an x-percent content of ZrO₂, for example Al₂O₃ with 9% ZrO₂=HPS9 or Al₂O₃ with 25% ZrO₂=HPS25). Preferably, the carrier layer has a carrier upper side and a carrier lower side on which metallizations can be applied. A distance between the carrier upper side and the carrier lower side, i.e. a thickness of the carrier layer, for example, has a value between 30 μm and 3 mm. The metallization is, for example, made of copper, a copper alloy, molybdenum Mo, tungsten W, a composite material or similar and has a thickness between 30 μm and 3 mm. For the formation of conductive tracks or connecting areas, the metallizations applied to the carrier layer are at least partially structured before and/or after the bonding process, e.g. etched away in order to electrically isolate individual areas of the metallization from each other.

Preferably, the passage recess is a passage bore which, in the case of an already sintered ceramic, is inserted mechanically and/or optically, for example by means of laser light, into the carrier layer. A “DCB process” (Direct Copper Bond Technology) is a process used, for example, to join metallizations or metal sheets (e.g. copper sheets or foils) with each other and/or with ceramic or ceramic layers, using metal or copper sheets or metal or copper foils with a layer or coating (melting layer) on their surface sides comprising a chemical compound of the metal and a reactive gas, preferably oxygen. In this process, described for example in US-PS 37 44 120 or in DE-PS 23 19 854, this layer or coating (melting layer) forms a eutectic having a melting temperature below the melting temperature of the metal (e.g. copper), so that by applying the foil to the ceramic and by heating all the layers these can be bonded to each other, namely by melting the metal or copper essentially only in the area of the melting layer or oxide layer.

In particular, the DCB process then includes the following process steps, for example:

oxidizing a copper foil to form a uniform copper oxide layer;

placing the copper foil on the ceramic layer;

heating the composite to a process temperature between about 1065° C. to 1083° C., e.g. about 1071° C.;

cooling down to room temperature.

An active brazing process, e.g. for joining metallizations or metal foils, in particular also copper layers or copper foils with ceramic material, is understood to be a process which is also specifically used for the production of metal-ceramic substrates. A connection between a metal foil, for example copper foil, and a ceramic substrate, for example aluminium nitride ceramic, is produced at a temperature between approx. 650-1000° C. using a brazing alloy which also contains an active metal in addition to a main component, such as copper, silver and/or gold. This active metal, which is for example at least one element of the group Hf, Ti, Zr, Nb, Ce, forms a bond between the solder and the ceramic by chemical reaction, while the bond between the solder and the metal is a metallic brazing bond.

According to a further embodiment of the present invention, it is provided that a certain electrical resistance of the via is set by the method. For example, the electrical resistance is set by the size of the recess passage and/or the fill level of the through hole. This makes it possible to achieve a targeted electrical resistance with advantage. In particular, the selection of the size and/or fill level of the passage recess can be adapted to the respective expansion coefficients of the carrier layer on the one hand and a coating or filling forming the passage recess on the other hand in order to reduce the probability of thermomechanical stresses forming in the finished carrier layer.

In a further embodiment of the present invention, it is provided that an electrical resistance of the via is set by setting one or more process parameters of the connection process. This allows the electrical resistance of the vias to be adjusted with advantage and without great additional effort. For example, a curing of the paste during the bonding process changes an electrically effective degree of filling of the passage recess or the wall thickness of the filler metal in the passage recess. Preferably, pastes comprising or filled with a glass solder or ceramic powder are used for this purpose, the glass solder or ceramic powder representing a matrix of non-conductive material in the bonding process.

It is convenient that an inner side of the passage recess is covered with a paste, wherein the passage recess is preferably filled at least partially, preferably completely. By covering or coating the inside of the passage recess, the paste is advantageously applied in the area in which the paste forms the passage recess according to the method. It is conceivable that the paste only covers a part of the inside of the passage recess. In order to be able to provide an electrically conductive connection between the top side of the carrier and the underside of the carrier later, the paste extends continuously from the top side of the carrier to the underside of the carrier. Preferably, the passage recess is partially filled at the edge or completely filled with the paste. This ensures that the vias are as stable as possible. In addition, complete filling with the paste is simpler than a process in which a metal block is inserted into the passage recess to form the vias. It is also conceivable that a filling degree of the through hole is reduced in the finished state by the connection method, especially by the selected parameters of the connection method, compared to the filling degree during filling or immediately after filling the passage recess. In particular, it is conceivable that a cavity enclosed in the via is formed during the bonding process. It is particularly preferred that the degree of filling has a value between 20% and 100%, preferably between 40% and 100% and particularly preferred between 60% and 100% after the bonding process. The skilled person understands the degree of filling in particular as a ratio between a material-filled volume fraction and the total volume of the unfilled passage recess. The unfilled passage recess is limited by the carrier layer and ends flush with the top side and/or underside of the carrier.

According to a further embodiment of the present invention, it is provided that the passage recess is configured as a coating of the inner side of the passage recess having a coating thickness, wherein the parameters determining the bonding process are set in such a way that a certain coating thickness is achieved. For a given quantity of paste applied to the inside of the passage recess, the process pressure in a recipient, for example, is decisive for the formation of a cavity in the passage recess. For a complete filling of the vias, a pressure as low as possible in the range below 1 mbar, preferably below 10⁻² mbar, especially preferred below 10⁻⁴ mbar is necessary. However, in order to achieve a cavity by a passage recess not completely filled with paste, in addition to the process pressure, a minimum residence time of the paste components of the process-compliant bonding process in the melting range of less than 60 min, preferably less than 30 min and particularly preferred less than 10 min is required in order to prevent diffusion of the molten paste components into the metallization. If the solder (active solder or CuO) remains in the molten state for a longer period of time, especially if it remains there for more than 10 minutes, the additives which lower the melting point diffuse into the metallization with increasing time and would thus reduce the metallic volume forming the passage recess. The electrical resistance of the via is advantageously adjusted by the coating thickness. In particular, it is conceivable that a ratio of a coating thickness to a diameter defined by the inside of the passage recess has a value between 0.05 and 0.5, preferably between 0.1 and 0.45 and particularly preferably between 0.15 and 0.35.

In a further embodiment of the present invention it is provided that a paste having an additional material, in particular with an additional material lowering the melting temperature, is used. This advantageously ensures that the paste melts at the temperatures occurring in the bonding process and subsequently hardens to form the passage recess. An active soldering used in the active soldering process is preferably based on a eutectic mixture of silver and copper, the melting temperature of which is essentially 780° C. and has a composition of 72% by weight (Ag) to 28% by weight (Cu). Preferably, an active metal such as Ti, Zr and/or Hf is added to the active solder.

Preferably, it is provided that the additive material comprises indium, tin and/or gallium, preferably in a concentration of 0.1 to 20% by weight, preferably in a concentration of 0.25 to 15% by weight and more preferably in a concentration of 0.5 to 10% by weight. By adjusting these concentrations, the flow properties of the active solder can be influenced advantageously. In particular, the concentration interval between 0.5 and 10% by weight proved to be advantageous with regard to the flow behaviour when forming the passage recess or filling the passage recess. The content of the additive material is preferably adapted to the desired fill level of the through hole.

In a further embodiment of the present invention, it is provided that the paste be applied by means of a printing process, in particular a 3D printing process, and/or a screen printing process and/or stencil printing. It is conceivable that a closure layer is provided during filling, in particular when filling by screen printing, wherein the closure layer limits the opening to one side and prevents the paste from escaping during filling. Preferably, the passage recess is made of a porous material or a non-porous material. The use of a porous material allows a vacuum to be applied to draw the paste into the passage recess. It is also conceivable that the closure layer may be spaced from the upper side and/or lower side of the carrier to facilitate the connection between the vias and the metallization.

According to a further embodiment of the present invention, it is provided that the passage recess has a diameter between 0.01 mm and 5 mm, preferably between 0.03 mm and 2.5 mm and more preferably between 0.05 mm and 2 mm. In particular for passage recesses with a diameter between 0.05 and 2.5 mm, the requirements for the carrier layer regarding electrical resistance, conductivity and thermal shock resistance are ensured.

In particular, it is provided that the passage recess will be partially, and in particular only partially, filled with the paste, the passage recess being preferably filled between 20% and 90%, preferably between 40% and 80% and in particular between 60% and 75%, prior to the bonding process. Surprisingly, it turned out that a partial filling of the passage recess is sufficient to realize a process-safe electrically conductive connection by the manufactured via. Preferably, the passage recess is only partially filled with a screen printing process and/or a 3D printing process. In the case of partial filling, it is preferable to ensure that the inside of the passage recess is covered. This ensures that an electrically conductive connection can be provided by the paste according to the connection procedure. For example, the inside is specifically covered or coated, or the slightly liquid paste is applied to the inside during the bonding process. The carrier layer, for example, could be inclined for that. Furthermore, it is conceivable that the passage recess will be completely filled in the beginning and a part of the paste will then be removed from the passage recess before the bonding process.

In a further version of the present invention, it is provided that the passage recess is partially filled with an electrically conductive material according to the bonding process, wherein the passage recess is preferably filled between 20% and 80%, preferably between 40% and 75% and particularly preferably between 60% and 70% before the bonding process. For example, the conductive material is a metal, especially copper. In particular, it is provided to reduce the filling level during the bonding process. In other words: a part of the paste embedded in the passage recess evaporates during the bonding process. It is also conceivable that the paste or the composition of the paste and/or the bonding process are designed in such a way that a specific reduction of the filling level can be expected and thus the conductivity of the via is restricted.

Preferably, it is provided that the passage recess is conically shaped. The conical shape supports the flow of the paste from the carrier layer into the passage recess and, for example, the degree of inclination of the passage recess can be used to adjust the filling in a controlled manner during the bonding process.

In a further embodiment of the present invention, it is provided that the paste

is arranged and/or configured on the carrier layer in such a way that paste arranged at the edge of the passage recess flows from the carrier layer into the passage recess during the bonding process and/or

is arranged in the passage recess by means of screen printing. For example, it is conceivable that the passage recess would be dimensioned in such a way that the paste reaches or is pulled into the passage recess by an adhesion effect during the bonding process. A movement of the carrier layer can also support or cause the paste to flow in.

Preferably, it is provided that a content of an electrically conductive material in the paste to the total paste has a value between 0.2 and 0.8, preferably between 0.35 and 0.75 and preferably between 0.4 and 0.6. This allows the electrical conductivity and the filling level of the passage recess to be influenced in a targeted manner, advantageously.

Another object of the present invention is a carrier layer having a via, in particular produced by a method according to one of the preceding claims, comprising:

a ceramic support layer

a passage recess formed in the carrier layer, wherein the passage recess is at least partially filled with metal that can contribute to the electrical conduction, preferably between 20% and 100%, preferably between 40% and 100%, and more preferably between 60% and 100%. All features described for the method according to the present invention and their advantages can be transferred analogously to the inventive carrier layer and vice versa.

Further advantages and specifics result from the following description of preferred embodiments of the object of the invention with reference to the attached figures. Individual characteristics of the individual embodiment can be combined with each other within the meaning of the invention.

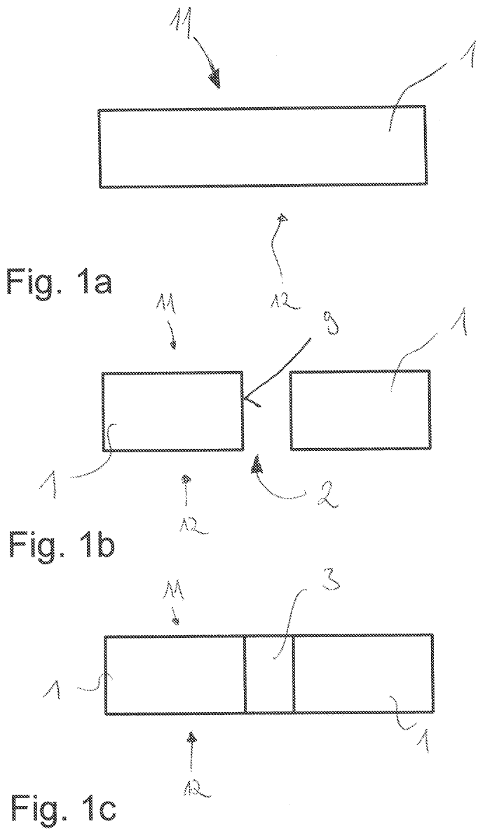

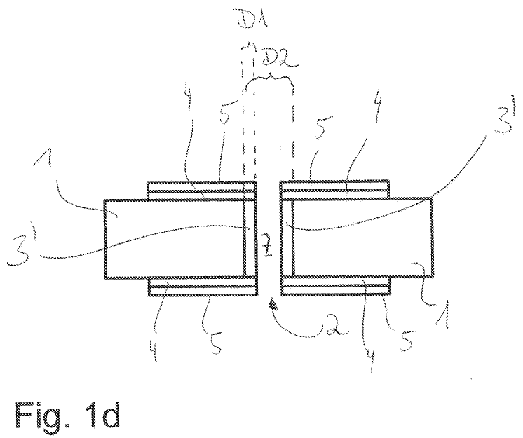

FIGS. 1a to 1d show a method for producing a 3′ via in a carrier layer 1 made of a ceramic according to an exemplary embodiment of the present invention. This is preferably a ceramic-containing carrier layer 1 which is advantageous for special applications and is intended as a carrier for electrical or electronic components. For the electrically conductive connection of the individual electrical or electronic components, metallizations for the formation of conductor tracks on a carrier top side 11 are provided, in particular. In order to reduce parasitic induction effects and make optimum use of the carrier layer 1, it is advantageous to arrange metallizations on the carrier underside 12 opposite to the carrier top side 11 in addition to the metallizations on the carrier top side 11. For the connection of the metallizations or a metallization 5 on the carrier top side 11with those on the carrier underside 12, a 3′ via is preferably provided. In order to form the passage recess 3′, a passage recess 2, in particular a passage recess, is preferably first inserted into the carrier layer 1 comprising the ceramic, as shown in FIG. 1b. The passage recess has a diameter of D2. A paste 3 is then inserted into the passage recess 2 (see FIG. 1c). The paste 3 is preferably a paste comprising an active solder material and/or a copper. It is preferred that the paste 3 at least partially, preferably completely covers an inner side 9 of the passage recess 2.

In addition, it is provided that the metallization is applied to the carrier top side 11 and to the carrier underside 12 by means of an active soldering process using an active solder 4. It is provided that the via 3′ is formed from the paste 3 in the passage recess 2 by means of the active soldering process within the framework of the bonding process. This makes it possible to realize via 3′ together with the bonding process of metallization or metallization 5 in one method step. Preferably it is provided that the via 3′ is formed by a coating with a coating thickness D1 on an inner side 9 of the passage recess. In particular, in the finished state, the coating attached to the inner side 9 and a coating-free core area 7 are arranged in the passage recess 2. Preferably, the volume ratio of the attached coating and the coating-free core area 7 can be used to adjust the electrical conductivity of the via 3′ in a targeted manner. Furthermore, it is preferably provided that the metallization 5 extends over the coating-free core area 7, in particular that it completely covers the coating-free core area.

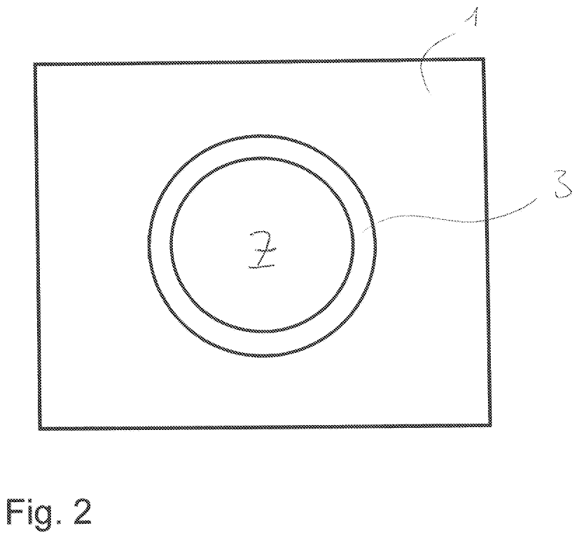

FIG. 2 shows a top view on a carrier layer 1 or a cross section through the carrier layer 1 with a via 3′ according to an exemplary embodiment of the present invention. The top view shows the coating arranged on the inner side 9 of the passage recess 2, which encases or surrounds the coating-free core area 7. The coating-free core region 7 preferably has a radius, the ratio of the radius of the coating-free core region 7 to the inner radius of the passage opening 2 having a value between 0.2 and 0.9, preferably between 0.4 and 0.8 and particularly preferably between 0.5 and 0.7.

Reference sign:

1 carrier layer

2 passage recess

3 paste

3′ via

4 active solder

5 metallization

7 core area

9 inner side

11 carrier top side

12 carrier underside

D1 coating thickness

D2 diameter

1. A method for forming a via (3) in a carrier layer (1) made of a ceramic comprising:
providing the carrier layer (1),
realizing a passage recess (2) in the carrier layer (1),
at least partially filling the passage recess (2) with a paste (3), and
performing a bonding process by means of an active soldering process or a DCB process for bonding a metallization (5) to the carrier layer (1), the via (3′) being realized from the paste (3) in the passage recess (2) when the bonding process is performed.

2. The method according to claim 1, wherein a certain electrical resistance of the via (3′) is set by the method.

3. The method according to claim 1, wherein an electrical resistance of the via (3′) is set by setting one or more process parameters of the bonding process.

4. The method according to claim 1, wherein an inner side (9) of the passage recess (2) is covered with a paste (3), the passage recess (2) preferably being at least partially filled.

5. The method according to wherein the via (3′) is formed as a coating of the inner side (9) of the via (2) having a coating thickness (D1), the bonding process being configured such that a certain coating thickness is obtained.

6. The method according to claim 1, wherein a paste (2) having an additive material is used.

7. The method according to claim 6, wherein the additive material comprises indium, tin and/or gallium, preferably in a concentration of 0.1 to 20% by weight.

8. The method according to claim 1, wherein the metallic components of the paste (3) are applied by means of a printing process and/or a screen printing process and/or a stencil printing process.

9. The method according to claim 1, wherein the passage recess (2) has a diameter (D2) or equivalent cross-sectional area between 0.01 mm and 5 mm.

10. The method according to claim 1, wherein the passage recess (2) is partially filled with the paste (3), the passage recess being preferably filled between 20% and 90%.

11. The method according to claim 1, wherein the passage recess (2) is partially filled with an electrically conductive material after the bonding process, the passage recess (2) being preferably filled between 20% and 80% before the bonding process.

12. The method according to claim 1, wherein the passage recess (2) is conically shaped.

13. The method according to claim 1, wherein the paste (3) is arranged and/or configured on the carrier layer (1) in such a way that paste arranged at the edge of the passage recess (2) flows from the carrier layer (1) into the passage recess (2) during the bonding process, and/or
is arranged in the passage recess (1) by means of screen printing.

14. The method according to claim 1, wherein a content of an electrically conductive material in the paste (3) to the total paste (3) has a value between 0.2 and 0.8.
